(19) United States
(12) Patent Application Publication
(10) Pub. No.: US 2023/0193455 A1
(43) Pub. Date: Jun. 22, 2023

(54) VACUUM CHAMBER, VACUUM SYSTEM AND METHOD FOR VACUUM PROCESSING

(71) Applicant: Applied Materials, Inc., Santa Clara, CA (US)

(72) Inventors: Wolfgang MUTLU, Frankfurt am Main (DE); Ursula Ingeborg SCHMIDT, Alzenau (DE)

(21) Appl. No.: 17/985,734

(22) Filed: Nov. 11, 2022

Related U.S. Application Data
(60) Provisional application No. 63/290,478, filed on Dec. 16, 2021.

(51) Int. Cl. C23C 14/54; C23C 14/28

(52) U.S. Cl. CPC C23C 14/541; C23C 14/28

(57) ABSTRACT

A vacuum chamber for vacuum processing is provided. The vacuum chamber includes at least one device comprising at least one treated surface, the at least one treated surface being provided by ultra-short pulse laser surface treatment. The at least one treated surface is positioned and shaped so as to provide thermal energy to and/or absorb thermal energy from a component, the component being positioned in a relative position to the at least one treated surface.

### FIELD OF INVENTION

The present disclosure relates to vacuum systems and in particular to vacuum chambers. In further detail, the present disclosure relates to vacuum processing of substrates in vacuum processing systems and chambers.

### BACKGROUND

Vacuum systems are used for a wide range of applications. Many processing operations like e.g. manufacturing processes, measurement processes and the like are carried out under vacuum conditions.

One example for such vacuum systems and processes is substrate processing. Substrate processing may include e.g. material deposition processes for manufacturing several devices. Material deposition processes may e.g. be used in the display manufacturing industry, packaging industry, battery manufacturing industry, thin-film processing industry, semiconductor manufacturing industry, TFT manufacturing industry, solar cell manufacturing industry, etc., whereby several applications like e.g. physical vapor deposition and chemical vapor deposition are carried out under vacuum conditions.

Vacuum processing, i.e. processing under vacuum conditions, includes several challenges. The applied vacuum conditions may result in an altered behavior of substances, objects, materials and the like that are placed in the vacuum, due to the altered pressure conditions. For example, outgassing of materials in vacuum may often be observed, especially when composites of different materials are used like e.g. devices with coatings on their surface.

Further, the process environment plays an important role in several physical or chemical occurrences. For example, energy transfer under vacuum conditions may be difficult due to the lack of gaseous molecules in between objects where energy transfer shall occur.

In light of the above, it is beneficial to provide apparatuses and processes for an improved energy transfer.

### SUMMARY

In light of the above, a vacuum chamber, a vacuum system and a method for vacuum processing according to the independent claims are provided.

According to an aspect of the present disclosure, a vacuum chamber for vacuum processing is provided. The vacuum chamber includes at least one device comprising at least one treated surface, the at least one treated surface being provided by ultra-short pulse laser surface treatment. The at least one treated surface is positioned and shaped so as to provide thermal energy to and/or to absorb thermal energy from a component, the component being positioned in a relative position to the at least one treated surface.

According to a further aspect of the present disclosure, a vacuum system including at least one vacuum chamber according to any of the embodiments described herein is provided.

According to a further aspect of the present disclosure, a method for controlling a temperature in a vacuum system is provided. The method includes treating at least one surface with an ultra-short pulse laser to obtain at least one treated surface, providing the at least one treated surface in a vacuum chamber, positioning a component relative to the at least one treated surface, and providing thermal energy to and/or absorbing thermal energy from the component with the at least one treated surface.

Embodiments are also directed at apparatuses for carrying out the disclosed methods and include apparatus parts for performing each described method aspect. The method aspects may be performed by way of hardware components, a computer programmed by appropriate software, by any combination of the two or in any other manner. Furthermore, embodiments according to the present disclosure are also directed at methods for operating the described apparatus. It includes method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of a vacuum chamber according to embodiments described herein;

FIG. 2 shows a schematic view of a vacuum chamber according to embodiments described herein;

FIG. 3 shows a schematic view of a vacuum chamber according to embodiments described herein,

FIGS. 4a to 4c show schematic views of a vacuum chamber according to embodiments described herein;

FIGS. 5a to 5c show schematic views of a treated surface according to embodiments described herein; and

FIG. 6 shows a flow diagram of a method according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Within the following description of the drawings, the same reference numbers refer to the same or similar components. Generally, only the differences with respect to the individual embodiments are described. Unless specified otherwise, the description of a part or aspect in one applies to a corresponding part or aspect in another embodiment as well.

### GENERAL EMBODIMENTS

In vacuum, thermal transfer between objects or surfaces is more difficult to achieve since gas molecules for thermal convection may not be present or in such a low amount that an effective thermal transfer may not be provided. High efforts for cooling, and/or high efforts for heating particular devices or objects in a vacuum system may thus be made. Especially, cooling of sensitive devices such as e.g. substrates in a deposition apparatus, and heating of devices such as e.g. crucibles to provide a deposition material, is beneficial for the overall process to increase yield and to decrease costs and power supply.

To provide an effective thermal transfer in vacuum, good thermal emissivity characteristics, i.e. good thermal absorption and thermal radiation properties, of devices provided in the vacuum are beneficial. Accordingly, it is beneficial to use materials in vacuum systems that combine good thermal radiation/absorption while being usable under (high) vacuum conditions. However, vacuum-compatible materials show insufficient thermal radiation characteristics which is why normally, the vacuum-compatible materials are coated with thermal radiation/absorption enhancing materials like e.g. coating the materials with titanium. However, introduction of further coating materials may disadvantageously affect the vacuum compatibility e.g. because negative effects like outgassing of the materials are enhanced. Thus, it is beneficial to increase thermal radiation and/or absorption properties of materials while providing high compatibility under vacuum conditions.

According to embodiments that can be combined with any other embodiment described herein, vacuum compatible materials with improved thermal radiation and/or thermal absorption properties are provided. The materials may be used in any vacuum system or vacuum environment, i.e. under vacuum conditions. The materials may be used with plates, objects, devices and/or any other form of two- or three-dimensional shapes. Particularly, the plates, objects and devices include at least one surface including the material having improved thermal radiation and thermal absorption properties. The materials, i.e. the at least one surface made of the material, may be treated materials, particularly laser treated materials like ultra-short pulsed laser treated materials.

According to embodiments that can be combined with any other embodiment described herein, “vacuum conditions” or a “vacuum environment” as used herein include pressure conditions in the range of below 10⁻¹ mbar or below 10⁻³ mbar, such as 10⁻⁷ mbar to 10⁻² mbar. Further, pressure conditions of 10⁻⁸ mbar to 10⁻¹¹ mbar may be included. Vacuum conditions may be of natural origin and/or applied e.g. through the use of vacuum pumps or other vacuum creating techniques.

According to embodiments that can be combined with any other embodiment described herein, the at least one surface of the plates, objects and devices is a treated surface, particularly a “deliberately treated” surface. A “treated” or “deliberately treated” surface as used herein may be understood as a surface of a material or device, plate and/or object including the material, that has been worked with a laser, particularly an ultra-short pulse laser. Accordingly, the worked or treated surfaces may also be referred to as “textured” surfaces. Particularly, the at least one surface may include or may be made of a metallic material. The metallic material may be treated or textured by the laser, i.e. by the ultra-short pulse laser. The one or more surfaces may be an ultra-short pulsed laser treated surface. Particularly, the term “treated surface” may also be used to describe a surface of a specific device, i.e. a surface of a device that has been treated by ultra-short pulse laser treatment. In contrast, an “untreated” surface may be understood as a surface that has not been particularly provided with a laser treatment according to embodiments described herein.

Compared to the prior art, the treated or textured surfaces have enhanced and/or improved emissivity properties, i.e. high thermal radiation properties and/or high thermal absorption properties. In other words, absorption and/or radiation of electromagnetic waves (e.g. in the infrared spectrum and/or the visible spectrum) may be enhanced and/or improved. The enhanced and/or improved properties may be provided to the surface by processing or texturing of the surface with the laser, i.e. the ultra-short pulse laser, such that a “treated” or “deliberately treated” surface is obtained. Particularly, the treated or textured surface may include improved electromagnetic radiation and/or absorption properties compared to surfaces that have not been (deliberately) treated or textured.

According to embodiments that can be combined with any embodiment described herein, the objects, plates and devices may include a material, particularly a metallic material, having a treated surface. In other words, the objects, plates and devices may include at least one treated surface. The at least one treated surface may include a metallic material. The at least one treated surface may include a metallic material to provide at least one treated metallic surface. Particularly, the at least one treated surface may be made of the metallic material to provide the at least one treated metallic surface. The material, i.e. the metallic material, may be a transition metal, an alkaline earth metal, a metal of the boron group, a metal alloy and/or any combinations thereof. The material may be selected from the group of copper, molybdenum, nickel, magnesium, alumina, stainless steel, brass and/or any combinations thereof like e.g. an AlMg alloy.

As used throughout this disclosure, the term “emissivity” may be understood as the ratio of electromagnetic radiation of a surface of a material to the radiation from an ideal black surface at the same temperature. The ratio may vary from 0 to 1 wherein a value close to 1 may describe emittance of radiation at a high rate. Further, the term “emissivity” may also be understood in that a high emissivity corresponds to high absorption of electromagnetic radiation. Throughout the present disclosure, the terms “electromagnetic radiation” and “thermal radiation” may be understood synonymously. Accordingly, a surface as described herein having a “high emissivity” or “improved emissivity” may be understood as a surface having high thermal radiation and/or high thermal absorption rates. According to examples as provided herein, the emissivity may be measured or determined at 100° C. It is to be understood that the improved emissivity may be valid in other temperature ranges, particularly in higher temperature ranges well above 100 C°.

As used throughout the present disclosure, the term “emissivity difference” may be understood as the delta between the emissivity of a treated surface and an untreated surface, i.e. of a surface that has been treated with an ultra-short pulse laser according to embodiments described herein and a surface that has not been treated with an ultra-short pulse laser.

According to embodiments that can be combined with any other embodiment described herein, an emissivity difference between the treated surface and an untreated surface including or being made of the same material, may be in the range of 0.50 to 0.85, particularly in the range of 0.60 to 0.83, more particularly in the range of 0.70 to 0.81. Particularly, the emissivity difference between the at least one treated metallic surface and the untreated metallic surface including or being made of the same metallic material, may be in the range of 0.50 to 0.85, particularly in the range of 0.60 to 0.83, more particularly in the range of 0.70 to 0.81. The emissivity may be measured or determined according to embodiments described herein.

According to embodiments that can be combined with any other embodiment described herein, the ultra-short pulse laser treatment of the surface may result in a pattern or shape of the treated surface, e.g. a specific or predetermined pattern or shape. The treated surface may include a pattern. Depending on the type of pattern provided, the electromagnetic emission and/or absorption may be adapted. In other words, the pattern, structure or shape provided at the treated surface of the metallic material may influence the thermal radiation and/or thermal absorption properties of the treated surface, and may particularly improve the thermal radiation and/or thermal absorption properties compared to an untreated surface.

According to embodiments that can be combined with any other embodiment described herein, a surface of an object, plate, device and the like may be treated with an ultra-short pulse laser surface treatment. The ultra-short pulse laser or laser may provide a laser beam to the surface for altering the surface. It is to be understood that an “ultra-short pulse laser surface treatment” is directed to the treatment of a surface area, i.e. that the laser treatment is directed to a whole surface or surface portion and not to a particular point of a surface as is e.g. the case for laser welding or laser cutting at precise/particular points of a plate or material.

Particularly, treatment of the surface with the ultra-short pulse laser may result in a pattern on the surface. The pattern may result from fast evaporation of surface material. The fast evaporation of the surface material may result from treatment within an ultra-short time span. For example, the surface may be treated with the laser beam for one or more femto-, pico- or microseconds. Depending on a treatment time, the resulting pattern may vary. Differently treated surfaces, i.e. different patterns provided on the surface, may result in different thermal radiation and/or absorption characteristics of the surface. For example, the pattern may include or be a crosshatch pattern. It is to be understood that various other pattern types may be provided at the treated surface. Further exemplarily, a lateral dimension of the pattern may be in a range of wavelengths in the infrared spectrum.

Particularly, the pattern or structure may include a plurality of features. A “feature” as provided herein may be understood as an elevation of the material. The plurality of features may be separated by a plurality of grooves. Accordingly, the plurality of features and the plurality of grooves may be provided in an alternating manner on the treated surface. Additionally or alternatively, the plurality of features and the plurality of grooves may be uniformly distributed on the at least one treated surface.

According to embodiments that can be combined with any other embodiment described herein, the treated surface or the treated metallic surface may have an emissivity of ≥ 0.3, particularly ≥ 0.5, more particularly ≥ 0.6, even more particularly ≥ 0.7 at 100° C. Particularly, the treated surface or the treated metallic surface may be or may include an alumina-magnesium-alloy having an emissivity of ≥ 0.3, particularly of ≥ 0.5, more particularly of ≥ 0.8 at 100° C. Additionally or alternatively, the treated surface or the treated metallic surface may be or may include copper having an emissivity of ≥ 0.3, particularly of ≥ 0.5, more particularly of ≥ 0.7 at 100° C. Additionally or alternatively, the treated surface or the treated metallic surface may be or may include stainless steel having an emissivity of ≥ 0.4, particularly of ≥ 0.6, more particularly of ≥ 0.9 at 100° C. Additionally or alternatively, the treated surface or the treated metallic surface may be or may include brass having an emissivity of ≥ 0.3, particularly of ≥ 0.4, more particularly of ≥ 0.6 at 100° C. Additionally or alternatively, the treated surface or the treated metallic surface may be or may include molybdenum having an emissivity of ≥ 0.4, particularly of ≥ 0.5, more particularly of ≥ 0.7 at 100° C.

According to embodiments, the treated materials, i.e. the at least one treated surface may be applied where thermal transfer is important in a vacuum environment. Accordingly, cooling and/or heating of objects, e.g. devices, may be improved and/or enhanced. Further, any application including thermal radiation and/or absorption may be improved by using the materials, i.e. the objects having at least one treated surface, as described herein. Thus, the materials, i.e. the one or more surfaces including or being made of the materials having the treated surface(s), may be used in various applications including a vacuum environment.

According to embodiments that can be combined with any other embodiment described herein, a vacuum chamber is provided. The vacuum chamber may be configured for applying vacuum conditions therein, e.g. high vacuum conditions, low vacuum conditions and/or combinations thereof. The vacuum chamber may be suitable for various applications where a thermal regulation is applied. The vacuum chamber includes at least one device comprising at least one treated surface, the at least one treated surface being provided by ultra-short pulse laser surface treatment. The at least one treated surface is positioned and shaped so as to provide thermal energy to and/or to absorb thermal energy from a component, the component being positioned in a relative position to the at least one treated surface.

According to embodiments that can be combined with any other embodiment described herein, the component may be another device according to embodiments described herein. The component may include at least one treated surface according to any of the embodiments described herein. The treated surface of the component may face the at least one treated surface of the device. The at least one surface of the device may provide thermal energy to the treated surface of the component and vice versa. The at least one surface of the device may absorb thermal energy from the treated surface of the component and vice versa. Accordingly, enhanced and/or improved heat transfer between the at least one device and the component, for example via the at least one treated surface of the at least one device and the treated surface of the component, may be provided.

### Applications

According to embodiments that can be combined with any other embodiment described herein, the vacuum chamber may be configured for processing a substrate. For example, the vacuum chamber may be provided in a vacuum system, particularly a vacuum processing system. The vacuum chamber may be configured for application in deposition processes like e.g. PVD processes, CVD processes, thermal evaporation, large area substrate processing, sputter processes and the like. As examples, the processes may be used in display manufacturing, battery manufacturing, thin-film processing, semiconductor manufacturing, TFT manufacturing, solar cell manufacturing, etc.

According to embodiments that can be combined with any other embodiment described herein, the vacuum chamber may include a substrate to be processed, i.e. the substrate may be processed by e.g. coating or deposition with/of a deposition material. The substrate may be made of different materials like glass, metal, semiconducting material, flexible material, polymers, etc. The substrate may e.g. be a large area substrate. However, any substrate that may be suitable for being coated can be processed in the vacuum chamber.

According to embodiments that can be combined with any other embodiment described herein, the vacuum chamber may include a material provision source. The material provision source may vary depending on the process carried out in the vacuum chamber. The material provision source may be an evaporation source like e.g. a crucible in fluid connection with a material delivery portion, a sputter cathode (array), and the like. Further, the material provision source may include a material delivery portion including a shower head having nozzles for providing a deposition material to the substrate. The material to be deposited may be a vaporized material, an ionized material, etc. Furthermore, the material provision source may have a substantially horizontal and/or a substantially vertical orientation.

According to embodiments that can be combined with any other embodiment described herein, the vacuum chamber may include a substrate support. The substrate support may be configured to support and/or transport the substrate during deposition. For example, the substrate transport may be a carrier, a rotatable drum, a substrate table, an E-Chuck and the like. the substrate support may include a robot arm.

According to embodiments that can be combined with any other embodiment described herein, the vacuum chamber may include at least one treated surface as described according to any of the embodiments herein. For example, the vacuum chamber may include one or more walls having a treated surface and/or a treated surface portion. The one or more walls may be configured for absorbing heat energy from inside the vacuum chamber. Accordingly, an overall temperature inside the vacuum chamber may be controlled and/or regulated. Advantageously, the overall temperature may be regulated solely by providing the at least one treated surface.

According to embodiments that can be combined with any other embodiment described herein, the vacuum chamber may include at least one device having at least one treated surface according to any of the embodiments described herein. The device may be any device for carrying out a procedural step in the vacuum chamber For example, the device may be a device used in a substrate processing system. Further exemplarily, the device may be a chamber wall of the vacuum chamber, a plate, a material provision source, a crucible, a substrate support, a heat shield and the like.

According to embodiments that can be combined with any other embodiment described herein, the vacuum chamber may include a plate including a treated surface. The plate may be arranged inside the vacuum chamber. The plate may be arranged adjacent to a heat source. The heat source may e.g. be a material provision source (operated at a high temperature). The plate may be configured for absorbing thermal radiation, particularly from a further device or component inside the vacuum chamber. For example, the plate may be configured to protect a further device or component from heat damage. The further device or component may be arranged between the heat source and the plate. The further device or component may e.g. include a temperature-sensitive material. The further device may be a substrate according to embodiments described herein.

Advantageously, the plate having the treated surface may be provided to protect other devices from excessive heat radiation. Due to the improved heat absorption properties, heat energy may be efficiently absorbed by the treated surface provided at the plate. In other words, the treated surface of the plate may absorb the heat energy and efficiently remove heat from the vacuum chamber and/or the device or component to be protected.

According to embodiments that can be combined with any other embodiment described herein, the vacuum chamber may include a device having a plurality of treated surface portions. The plurality of treated surface portions may be understood as distinct parts of one surface of a device (or component, respectively) that includes differently treated surface portions, i.e. surface portions having different patterns thereon. The plurality of treated surface portions may be provided consecutively or discontinuously, i.e. the plurality of treated surface portions may be provided distant from each other. It is to be understood that also some treated surface portions of the plurality of treated surface portions may be provided consecutively and some treated surface portions of the plurality of treated surface portions may be provided spaced apart from each other.

According to embodiments that can be combined with any other embodiment described herein, the vacuum chamber may include a device having one treated surface portion. It is to be understood that the one treated surface portion may be provided at a surface of a device that may, besides the one treated surface portion, provide a non-treated surface.

Advantageously, the one treated surface portion and/or the plurality of treated surface portions may allow for a punctuated enhanced thermal transfer. Accordingly, specific areas may be particularly provided with heat energy and/or at specific areas heat energy may particularly be removed. Accordingly, fine regulation of heat transfer may be provided. For example, a directed heating or cooling of devices, areas and the like may be beneficially provided.

According to embodiments that can be combined with any other embodiment described herein, the vacuum chamber may include more than one treated surface. Particularly, the vacuum chamber may include two or more treated surfaces, more particularly three or more treated surfaces or even four or more treated surfaces. Each of the treated surfaces may include a different pattern provided by the ultra-short pulse laser. Accordingly, each of the treated surfaces may provide different thermal radiation and/or absorption characteristics. For example, one treated surface may provide an emissivity E₁ ≥ 0.4 to 0.9 and another treated surface may provide an emissivity E₂ ≥ 0.5 to 0.9.

According to embodiments that can be combined with any other embodiment described herein, the vacuum chamber may include two treated surfaces, i.e. a first treated surface and a second treated surface. The first treated surface and the second treated surface may be opposite to each other. For example, the first treated surface may be provided at a first device and the second treated surface may be provided at a second device, opposite the first device.

Advantageously, the first treated surface at the first device may provide enhanced thermal radiation properties and the second surface at the second device may provide enhanced absorption properties such that thermal transfer between the first treated surface and the second treated surface is improved. Thus, a configuration of a first treated surface and a second treated surface opposing each other may exemplarily be used for heating a device like e.g. a crucible for evaporating material inside the crucible, while less power is consumed for providing heat energy from the first device to the second device.

### Detailed Applications

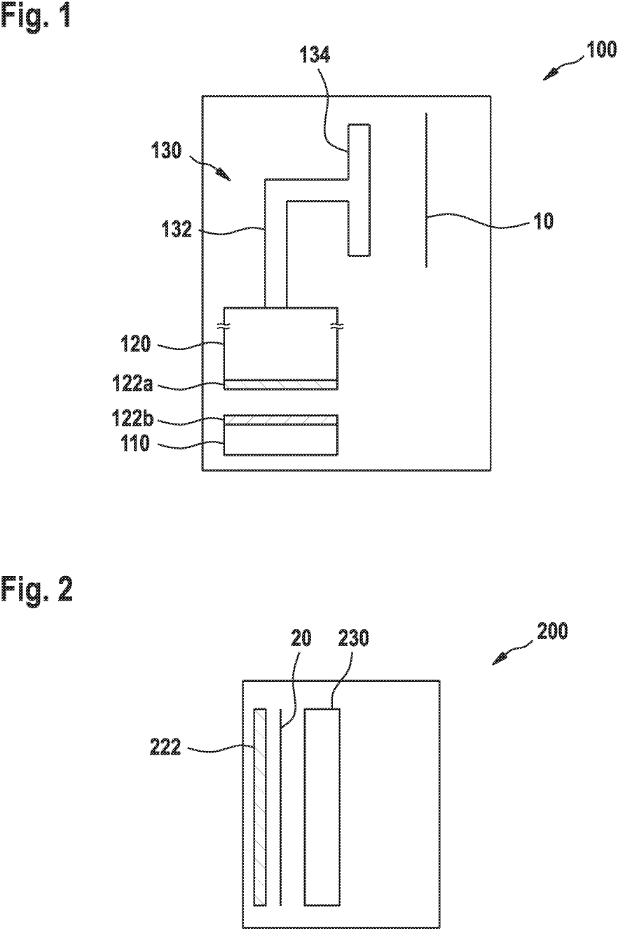

According to embodiments that can be combined with any other embodiment described herein and with exemplary reference to FIG. 1, a vacuum chamber 100 is provided. The vacuum chamber 100 may be configured for processing a substrate. The vacuum chamber 100 may include a heater 110. The heater may include a second treated surface 122b. The treated surface may be an ultra-short pulse laser treated surface. Accordingly, thermal emission of the heater at the surface may be enhanced.

According to embodiments that can be combined with any other embodiment described herein, the vacuum chamber 100 may include a material provision source 130. The material provision source may include a crucible 120. The crucible may be heated by the heater 110. The crucible may be configured for evaporating material, e.g. an organic and/or an inorganic material, inside the crucible. For example, the material inside the crucible may be heated to a temperature in the range of 200 to 900° C., particularly in the range of 500 to 800° C., more particularly in the range of 700 to 800° C. Furthermore, the crucible may be heated to a temperature in the range of 200 to 900° C., particularly in the range of 500 to 800° C., more particularly in the range of 700 to 800° C. The material inside the crucible may be a material to be deposited onto a substrate. The crucible may include a first treated surface 122a. The first treated surface 122a of the crucible may face a second treated surface 122b of the heater. The first treated surface 122a of the crucible may be configured to absorb thermal energy from the heater, i.e. from the second treated surface 122b of the heater. Accordingly, heat transfer between the heater 110 and the crucible 120 may be enhanced. Advantageously, less energy may be provided to the heater for achieving sufficient heating of the crucible due to the enhanced heat transfer via the first and the second treated surfaces 122a, 122b of the crucible and the heater. Accordingly, less energy input from the heater, i.e. an external thermo source, may be provided to the crucible.

According to embodiments that can be combined with any other embodiment described herein, the crucible may include more than one treated surface. For example, the crucible may include one or more side walls having differently treated surfaces. Accordingly, the treated surfaces may include different patterns provided by the ultra-short pulse laser surface treatment. Accordingly, a heat gradient may be provided at the side walls of the crucible to provide different temperatures at different positions inside the crucible to the material to be evaporated.

According to embodiments that can be combined with any other embodiment described herein, the crucible 120 may be in fluid connection with a material delivery portion 132. The material delivery portion 132 may include a distribution head 134 for providing the evaporated material to a substrate 10. Accordingly, evaporated material may be delivered from the crucible through the material delivery portion and through the destruction head to the substrate. For example, the distribution head 134 may include a plurality of nozzles to spray the material onto the substrate 10.

According to embodiments that can be combined with any other embodiment described herein and with exemplary reference to FIG. 2, a vacuum chamber 200 is provided. The vacuum chamber may include a material provision source 230 for providing a material to a substrate 20. The material provision source 230 may be arranged on one side of the substrate 20, i.e. the material provision source 230 may face the substrate at a front side of the substrate 20. On an opposite side adjacent to the substrate, i.e. adjacent to a back side of the substrate, a treated surface 222 according to any of the embodiments described herein, may be arranged. For example, a plate having a treated surface 222 may be arranged facing the back side of the substrate. The plate may be a metallic plate having the treated surface 222 thereon. Accordingly, the plate may have been treated with the ultra-short pulsed laser treatment to provide the treated surface 222.

According to embodiments that can be combined with any other embodiment described herein, the treated surface 222 may absorb heat energy, i.e. electromagnetic waves, provided by the material provision source towards the substrate. In other words, the plate and/or the treated surface 222 may be configured to cool the substrate. The material deposited by the material provision source may be deposited onto the substrate and transport a respective amount of heat towards the substrate. Accordingly, the plate and/or the treated surface 222 may be configured to absorb the heat provided by the deposition material. Thus, the substrate may be protected against heat damage. Further beneficially, deformation of the substrate due to heat impact may be reduced or avoided.

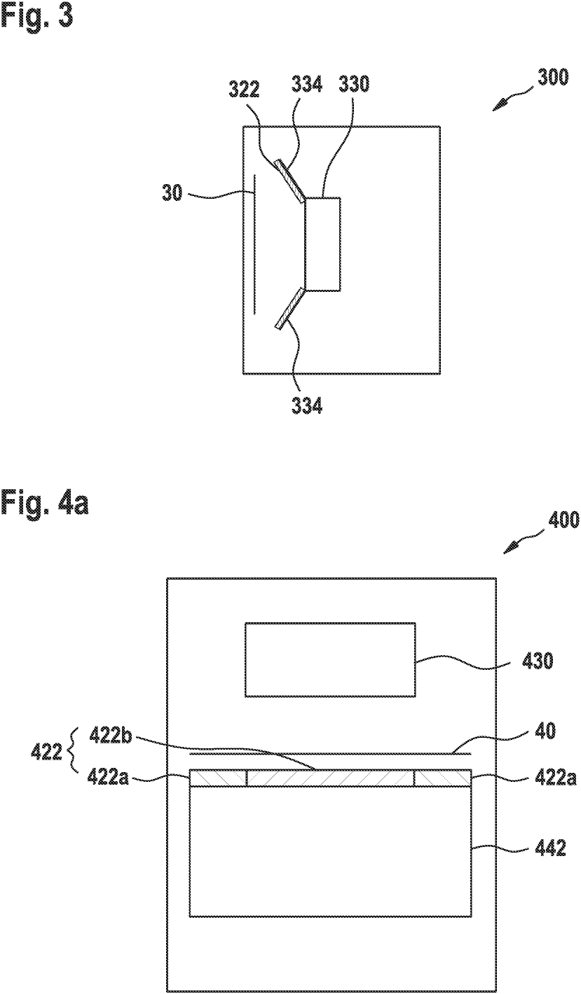

According to embodiments that can be combined with any other embodiment described herein and with exemplary reference to FIG. 3, a vacuum chamber 300 is provided. The vacuum chamber may include a material provision source 330 according to any of the embodiments described herein. The material provision source 330 may include one or more heat shields 334. Particularly, the material provision source 330 may include two heat shields. The one or more heat shields 334 may be arranged at opposing sides of the material provision source 330. The one or more heat shields 334 may each include a treated surface 322.

Advantageously, the one or more heat shields 334, i.e. the treated surface 322 of the one or more heat shields 334, may be configured for absorbing heat from the material provision source 330. Accordingly, less heat energy may reach the substrate 30. The one or more heat shields 334 including the treated surface 322 may be configured to cool the substrate. It is to be understood that the one or more heat shields may additionally or alternatively be arranged at different angles with respect to the material provision source. Further, the vacuum chamber 300 may additionally include the plate arranged at a back side of the substrate including the treated surface 222 as described with respect to FIG. 2.

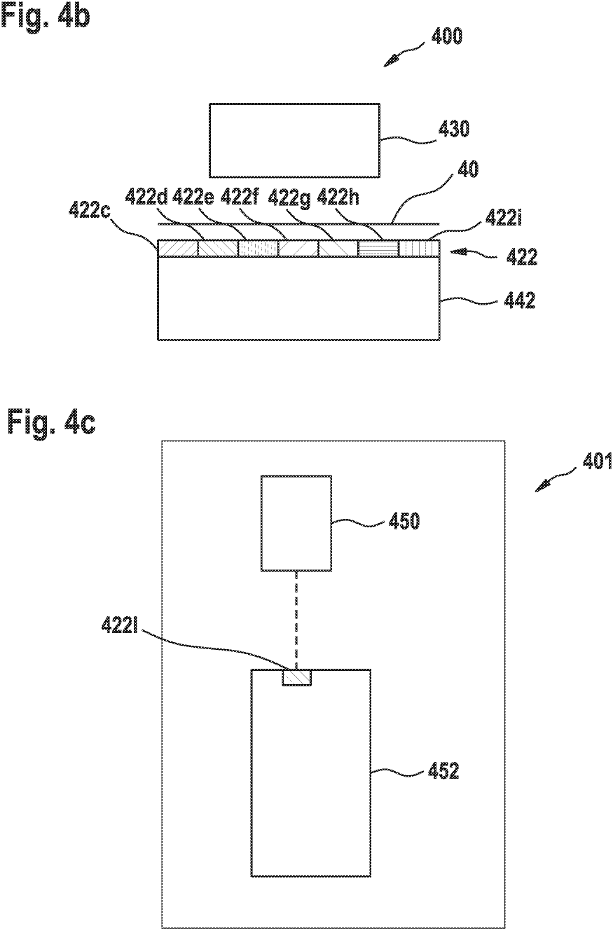

According to embodiments that can be combined with any other embodiment described herein and with exemplary reference to FIG. 4a, a substrate support arrangement 400 may be provided. The substrate support arrangement may be provided in a vacuum chamber according to any of the embodiments described herein. The substrate support arrangement 400 may include a substrate support 442 according to any of the embodiments described herein. The substrate support may be configured to support a substrate 40. Further, the substrate support arrangement may include a material provision source 430. The substrate support 442 may be arranged adjacent to the material provision source 430 and the substrate 40 may be arranged between the substrate support and the material provision source. A deposition material provided by the material provision source 430 may reach the substrate at an inner area of the substrate support. In other words, the material may be deposited on a center portion of the substrate. The deposition material may be provided within a material provision window.

According to embodiments that can be combined with any other embodiment described herein, the substrate support 442 may include a treated surface 422. The treated surface may include a first treated surface portion 422a and a second treated surface portion 422b. The first and the second treated surface portion s 422a, 422b may include different patterns according to any of the embodiments described herein. The first treated surface portion and the second treated surface portion may be provided in an alternating manner, i.e. two first treated surface portions may enclose one second treated surface portion. In other words, the two first treated surface portions may be provided at an outer area of the substrate support and the second treated surface portion may be provided in between the two first treated surface portions at the inner area of the substrate support. The dimension of the inner area of the substrate support may correspond to the material deposition window. The second treated surface portion 422b may correspond to the inner area of the substrate support. The first surface portion 422a may have a different emissivity compared to the second treated surface portion 422b, i.e. the first surface portion 422a may absorb heat energy to a greater extent compared to the second treated surface portion 422b and/or vice versa.

Advantageously, the first treated surface and the second treated surface may be configured to compensate a difference in heat provided at the substrate. The material provision source may provide the deposition material at high temperatures. To avoid damage to the substrate, the substrate support may compensate temperature differences at the substrate by providing different heat absorption characteristics such that a constant heat may be provided at the substrate, i.e. at a substrate surface (facing the substrate support).

According to embodiments that can be combined with any other embodiment described herein and with exemplary reference to FIG. 4b, the substrate support arrangement 400 may include the substrate support 442 having the treated surface 422. The treated surface may include a plurality of treated surface portions 422c - 422i. Each treated surface portion of the plurality of surface portions may include a different pattern according to any of the embodiments described herein. Accordingly, each of the treated surface portions 422c - 422i may have a different emissivity i.e. different absorption and/or radiation properties.

According to embodiments that can be combined with any other embodiment described herein, the plurality of treated surface portions may include three differently treated surface portions, particularly four differently treated surface portions, more particularly five differently treated surface portions, even more particularly six differently treated surface portions or more than six differently treated surface portions. The number of differently treated surface portions may be chosen in accordance with a gradient of heat emissivity, i.e. a temperature gradient, over the treated surface.

Advantageously, the plurality of treated surfaces may provide a temperature gradient or gradient of heat emissivity. Thus, e.g. different parts of the substrate may receive different temperatures. Depending on the pattern of the respective treated surface, the gradient may be adapted. It is to be understood that the more differently treated surface portions are included in the treated surface, the finer the temperature gradient may be set. It is further to be understood that such a gradient may be provided at other plates, object and devices as described herein.

According to embodiments that can be combined with any other embodiment described herein, the plurality of treated surface portions may be separated by untreated surface portions. As an example, a plurality of treated surface portions may be alternatingly arranged with a plurality of the untreated surface portions. A punctual temperature difference may, thus, be achieved.

According to embodiments that can be combined with any other embodiment described herein and with exemplary reference to FIG. 4c, a vacuum chamber 401 may be provided. The vacuum chamber may include a device, for example an electrically heatable substrate support 452, including at least one treated surface portion 4221. The electrically heatable substrate support may additionally be a substrate support according to any of the embodiments described herein. The vacuum chamber may include a measurement device 450. The measurement device may be a temperature measurement device. For example, the measurement device may include a pyrometer. The measurement device may be arranged such that a measurement can take place at the at least one treated surface portion 4221 or the at least one treated surface.

According to embodiments that can be combined with any other embodiment described herein, the measurement device may be an infrared (IR) camera. The IR camera may be used for measuring radiated or emitted IR radiation, particularly radiation emitted by the at least one treated surface. Accordingly, by providing the at least one treated surface and/or the at least one treated surface portion, high or improved emissivity may be provided to decrease measurement limits of the IR camera and/or to reduce measuring errors, since a reduced emissivity or a higher influence of extraneous light may be eliminated. Accordingly, by using a treated surface or surface portion according to embodiments described herein, measurement limits or errors of measurement devices may specifically be reduced or eliminated by enhancing the emissivity of the object to be measured. Advantageously, a measurement process may be improved and facilitated by improving emissivity of the object to be measured.

Advantageously, the at least one treated surface portion may enhance heat radiation to facilitate measurement of the temperature of the device having the at least one treated surface portion. For example, the pyrometer may be arranged such that a measuring beam may reach the at least one treated surface portion. Accordingly, measurement accuracy may be increased by enhancing heat radiation from the device of which the temperature is to be measured. Further advantageously, the treated surface portion may be arranged at any position of the device such that a temperature measurement may be allowed at positions of the device that are hardly accessible.

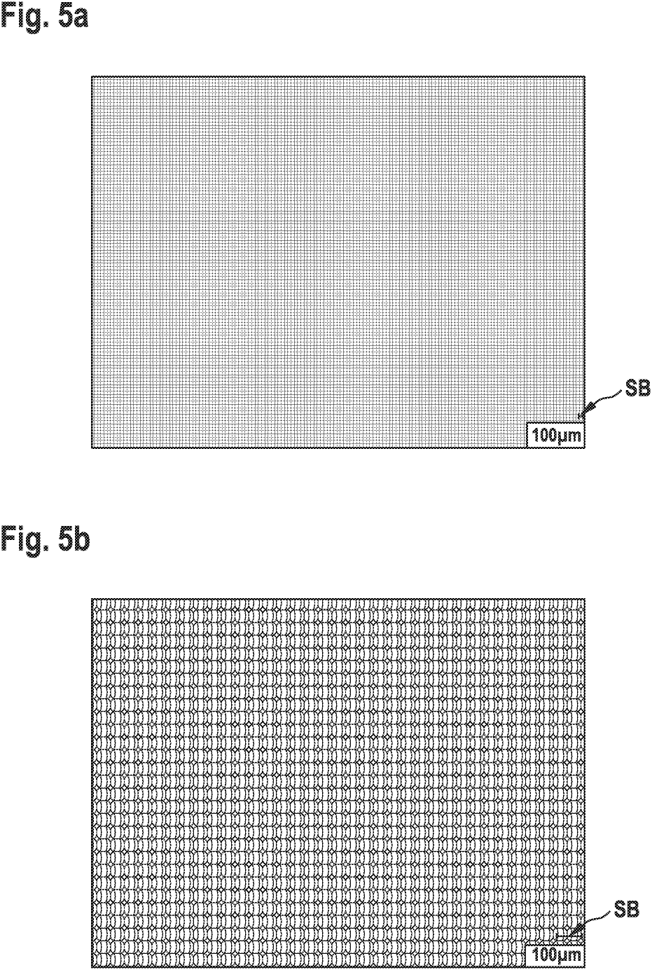

According to embodiments that can be combined with any other embodiment described herein and with exemplary reference to FIGS. 5a to 5c exemplarily schematically showing microscopy pictures at different magnifications, the treated surface may include a pattern. FIGS. 5a to 5c exemplarily show a pattern in different magnified views (50×, 200×, 500×) of a treated metallic material. For example, the pattern may include or be a crosshatch pattern. It is to be understood that the treated metallic material may include or consist of further types of patterns, and that a crosshatch pattern may be seen as a mere example. In FIGS. 5a to 5c, the scale bar SB indicates a lateral dimension of 100 µm.

According to embodiments that can be combined with any other embodiment described herein and with exemplary reference to FIG. 5a (50× magnification), the at least one treated surface may include a pattern. The pattern of the at least one treated surface may be a regular pattern. The pattern may include a plurality of features and a plurality of grooves, e.g. the plurality of features and the plurality of grooves may be provided uniformly and in an alternating manner. Viewed from a plan perspective, the plurality of features may be arranged in substantially straight horizontal rows and/or in substantially straight vertical lines. The term “substantially” as used herein may be understood particularly when referring to horizontal rows or vertical lines that, from a plan view, a deviation from the horizontal and/or vertical direction or orientation of ±20° or below, e.g. of ±10° or below is allowed.

According to embodiments that can be combined with any other embodiment described herein and with exemplary reference to FIG. 5b (200× magnification), the pattern may include a plurality of features and a plurality of grooves in an alternating manner. It is to be understood that the term “grooves” may include gaps, recesses and/or depressions where material has been removed by the ultra-short pulsed laser surface treatment from the surface. Accordingly, as an example, the pattern may include a honeycomb-like structure from a top view perspective (2D). According to embodiments, the plurality of features may contact each other and/or may be distinct from each other. A lateral dimension of one feature, i.e. a width and/or length of one feature, may be equal to or below 100 µm, for example between 100 µm to 20 µm, particularly between 80 µm to 30 µm, more particularly between 70 µm to 40 µm, even more particularly between 60 µm to 50 µm. In other words, each of the features of the plurality of features may have a width and/or length equal to or below 100 µm, for example between 100 µm to 20 µm, particularly between 80 µm to 30 µm, more particularly between 70 µm to 40 µm, even more particularly between 60 µm to 50 µm.

According to embodiments that can be combined with any other embodiment described herein and with exemplary reference to FIG. 5c (500× magnification), between two adjacent features, e.g. between two diagonally arranged features, of the plurality of features one or more depressions or recesses may be provided. The pattern may include a holey structure. The features may include various 2D or 3D shapes like e.g. substantially spherical, cuboid, circular, rectangular and the like and/or combinations thereof. The shape of the features may be dependent on a type of ultra-short pulsed laser treatment of the surface.

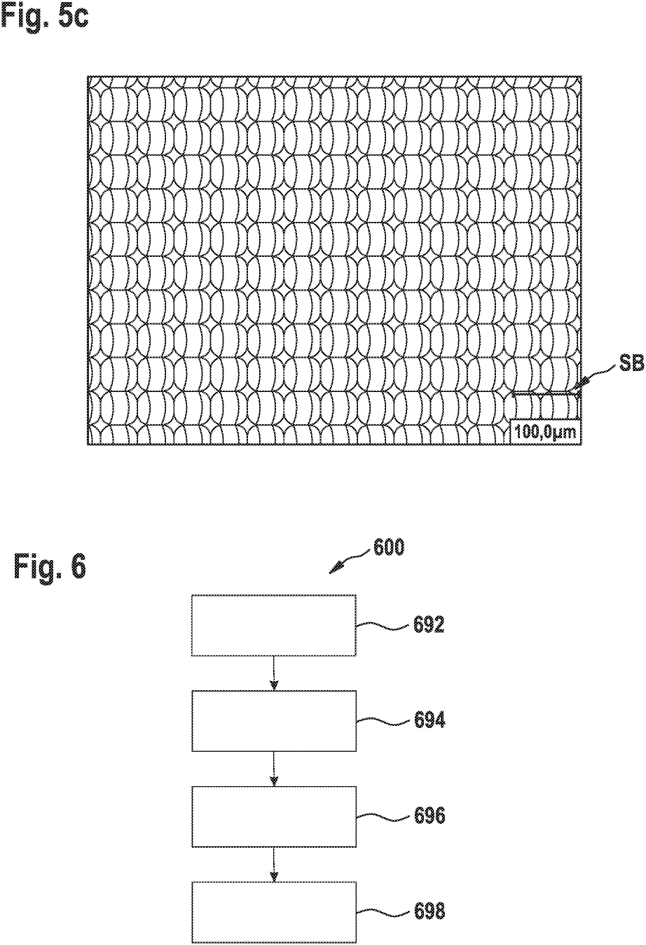

According to embodiments that can be combined with any other embodiment described herein and with exemplary reference to FIG. 6, a method 600 for controlling a temperature in a vacuum system is provided. The method includes treating (indicated by box 692 in FIG. 6) at least one surface with an ultra-short pulse laser to obtain at least one treated surface. The at least one treated surface is positioned and shaped so as to provide thermal energy to and/or absorb thermal energy from a component. The treated surface may be a treated surface according to any of the embodiments described herein. The method further includes providing (indicated by box 694 in FIG. 6) the at least one treated surface in a vacuum chamber, positioning (indicated by box 696 in FIG. 6) a component relative to the at least one treated surface, and providing (indicated by box 698 in FIG. 6) thermal energy to and/or absorbing thermal energy from the component with the at least one treated surface.

According to embodiments that can be combined with any other embodiment described herein, the component may be a component according to any of the embodiments described herein. The temperature may be controlled by providing the at least one treated surface according to any of the embodiments described herein.

### EXAMPLES

### Determination of Emissivity

The emissivity of surfaces may be measured according to the following:

According to embodiments, a sample with an exemplary size of 10 cm × 10 cm may be used. The sample may consist of a metal. Additionally, a black reference sample may be provided. The sample and the black reference sample may be provided in a furnace and heated to 100° C. The black reference sample is included in the measurement to display a sample with an emissivity of 1. When opening the furnace, a thermography image is taken immediately with an IR camera. From the IR-camera picture, the object temperature is determined from the black reference sample with the emissivity of 1. The emissivity of the sample is determined based on the measured radiation intensity, the object temperature, the temperature of the environment, and the camera specific wavelength dependent temperature sensitivity curve. The emissivity is determined of untreated and treated surfaces, i.e. of the surfaces of untreated and treated samples of different materials, all at 100° C.

In the following table, emissivity of untreated surfaces of different materials is provided.

TABLE 1

Emissivity of untreated surfaces of different materials

| (untreated) material | Sample 1 | Sample 2 | Sample 3 | Sample 4 | Sample 5 | Sample 6 | Average | Std. Dev. |
|---|---|---|---|---|---|---|---|---|
| AlMg | 0.19 | 0.2 | 0.18 | 0.18 | 0.19 | 0.21 | 0.19 | 0.01 |
| Cu | 0.15 | 0.13 | 0.25 | 0.14 | 0.19 | 0.22 | 0.18 | 0.04 |
| Stainless steel | 0.24 | 0.3 | 0.4 | 0.3 | 0.36 | 0.42 | 0.34 | 0.06 |
| Molybdenum | 0.1 | 0.1 | 0.2 | 0.1 | | | 0.13 | 0.04 |

In the following table, emissivity of treated surfaces of different materials is provided.

TABLE 2

Emissivity of (ultra-short pulse laser) treated surfaces of different materials

| (treated) material | Sample 1 | Sample 2 | Sample 3 | Sample 4 | Sample 5 | Sample 6 | Average | Std. Dev. |
|---|---|---|---|---|---|---|---|---|
| treated AlMg | 0.97 | 1.00 | 1.00 | 1.00 | 1.00 | 1.00 | 1.00 | 0.01 |
| treated Cu | 0.58 | 0.64 | 0.71 | 0.77 | 0.86 | 0.9 | 0.74 | 0.11 |
| treated stainless steel | 0.98 | 1.00 | 1.00 | 1.00 | 1.00 | 1.00 | 1.00 | 0.01 |
| treated brass | 0.74 | 0.72 | 0.72 | 0.76 | 0.71 | 0.74 | 0.73 | 0.02 |
| treated molybdenum | 0.83 | 0.73 | 0.65 | 0.60 | | | 0.70 | 0.09 |

In the following table, the average emissivity of the untreated and treated surfaces of the different materials is provided.

TABLE 3

Comparison of average emissivity of untreated and treated material samples, i.e. of untreated and treated surfaces

| Material | Average emissivity of untreated surface | Average emissivity of treated surface |
|---|---|---|
| AlMg | 0.19 | 1.00 |
| Cu | 0.18 | 0.74 |
| Stainless steel | 0.34 | 1.00 |
| molybdenum | 0.13 | 0.70 |

Tables 1 to 3 show that the treated surfaces of different materials show enhanced emissivity properties compared to untreated surfaces of the respective materials.

Beneficially, according to any of the embodiments described herein, a vacuum chamber, a vacuum system and a method for controlling a temperature is provided. The vacuum chamber includes a treated surface that may beneficially enhance and/or improve thermal radiation and/or thermal absorption properties of the material of which the surface is provided or which the surface includes. Thus, thermal management and temperature control in any process related to a vacuum can be improved. Further, higher yields can be achieved for e.g. manufacturing processes, since thermally related damage to devices, components and objects in the vacuum can be effectively prevented or avoided. Advantageously, the embodiments described herein may provide for an improved vacuum chamber, vacuum associated processes and systems.

Various further embodiments are provided in the present disclosure, some of which are listed in the below listing of clauses.

Clause 1: A vacuum chamber for vacuum processing, the vacuum chamber comprising:
at least one device comprising at least one treated surface, the at least one treated surface being provided by ultra-short pulse laser surface treatment;
wherein the at least one treated surface is positioned and shaped so as to provide thermal energy to and/or to absorb thermal energy from a component, the component being positioned in a relative position to the at least one treated surface.

Clause 2: The vacuum chamber according to clause 1, wherein the at least one treated surface comprises a metallic material to provide at least one treated metallic surface, particularly wherein the at least one treated surface is made of a metallic material to provide the at least one treated metallic surface.

Clause 3: The vacuum chamber according to clause 2, wherein an emissivity difference between the at least one treated metallic surface and an untreated metallic surface comprising or being made of the same metallic material, is in the range of 0.50 to 0.85, particularly in the range of 0.60 to 0.83, more particularly in the range of 0.70 to 0.81.

Clause 4: The vacuum chamber according to any of clauses 1 to 3, wherein the component is selected from the group of a temperature-controllable component, a measurement device and/or combinations thereof.

Clause 5: The vacuum chamber according to clause 4, wherein the temperature-controllable component comprises a substrate, a material provision source, a vacuum chamber wall and/or a substrate support.

Clause 6: The vacuum chamber according to any of clauses 1 to 5, wherein the vacuum chamber comprises the component.

Clause 7: The vacuum chamber according to any of clauses 1 to 6, wherein the at least one treated surface has an emissivity of ≥ 0.3, particularly ≥ 0.5, more particularly ≥ 0.6, even more particularly ≥ 0.7 at 100° C.

Clause 8: The vacuum chamber according to any of clauses 2 to 7, wherein the at least one treated metallic surface has an emissivity of ≥ 0.3, particularly ≥ 0.5, more particularly ≥ 0.6, even more particularly ≥ 0.7 at 100° C.

Clause 9: The vacuum chamber according to any of clauses 1 to 8, wherein the at least one treated surface comprises a plurality of features substantially uniformly distributed over the at least one treated surface, particularly wherein each feature of the plurality of features is separated by a groove between two adjacent features of the plurality of features.

Clause 10: The vacuum chamber according to any of clauses 2 to 9, wherein the metallic material is a transition metal, an alkaline earth metal, a metal of the boron group, a metal alloy and/or any combinations thereof.

Clause 11: The vacuum chamber according to any of clauses 2 to 10, wherein the metallic material comprises copper, molybdenum, nickel, magnesium, alumina, stainless steel, brass and/or any combinations thereof.

Clause 12: The vacuum chamber according to any of clauses 1 to 11, wherein the at least one treated surface comprises an alumina-magnesium-alloy having an emissivity of ≥ 0.5, particularly of ≥ 0.7, more particularly of ≥ 0.9 at 100° C.

Clause 13: The vacuum chamber according to any of clauses 1 to 12, wherein the at least one treated surface comprises copper having an emissivity of ≥ 0.5, particularly of ≥ 0.6, more particularly of ≥ 0.7, even more particularly of ≥ 0.8 at 100° C.

Clause 14: The vacuum chamber according to any of clauses 1 to 13, wherein the treated surface comprises stainless steel having an emissivity of ≥ 0.6, particularly of ≥ 0.8, more particularly of ≥ 0.9 at 100° C.

Clause 15: The vacuum chamber according to any of clauses 1 to 14, wherein the treated surface comprises brass having an emissivity of ≥ 0.6, particularly of ≥ 0.7, more particularly of ≥ 0.72 at 100° C.

Clause 16: The vacuum chamber according to any of clauses 1 to 15, wherein the treated surface comprises molybdenum having an emissivity of ≥ 0.6, particularly of ≥ 0.7, more particularly of ≥ 0.8 at 100° C.

Clause 17: The vacuum chamber according to any of clauses 1 to 16, wherein the at least one device is selected from the group of a chamber wall of the vacuum chamber, a plate, a material provision source, a substrate support, a shield and/or combinations thereof.

Clause 18: The vacuum chamber according to clause 17, wherein the vacuum chamber comprises a material provision source and a plate for absorbing thermal radiation from the material provision source.

Clause 19: The vacuum chamber according to clause 17, wherein the vacuum chamber comprises a material provision source comprising a crucible and a heater, the crucible having at least one first treated surface and the heater having at least one second treated surface, the at least one first treated surface and the at least one second treated surface facing each other.

Clause 20: The vacuum chamber according to clause 17, wherein the vacuum chamber comprises a substrate support, the substrate support having at least one treated surface portion.

Clause 21: The vacuum chamber according to clause 20, wherein the vacuum chamber further comprises a measurement device, the measurement device being arranged for measuring a value at the at least one treated surface portion.

Clause 22: The vacuum chamber according to any of clauses 1 to 21, wherein the vacuum chamber is a vacuum processing chamber for processing a substrate.

Clause 23: A vacuum system comprising: at least one vacuum chamber according to any of clauses 1 to 21.

Clause 24: The vacuum system according to clause 23, wherein the vacuum system is a substrate processing system.

Clause 25: A method for controlling a temperature in a vacuum system, the method comprising:
treating at least one surface with an ultra-short pulse laser to obtain at least one treated surface;
providing the at least one treated surface in a vacuum chamber;
positioning a component relative to the at least one treated surface; and
providing thermal energy to and/or absorbing thermal energy from the component with the at least one treated surface.

While the foregoing is directed to embodiments of the disclosure, other and further embodiments of the disclosure may be devised without departing from the basic scope thereof, and the scope thereof is determined by the claims that follow.

1. A vacuum chamber for vacuum processing, the vacuum chamber comprising:
at least one device comprising at least one treated surface, the at least one treated surface being provided by ultra-short pulse laser surface treatment;
wherein the at least one treated surface is positioned and shaped so as to one selected of the group of providing thermal energy to and absorbing thermal energy from a component, the component being positioned in a relative position to the at least one treated surface.

2. The vacuum chamber for vacuum processing according to claim 1, wherein the at least one treated surface comprises a metallic material to provide at least one treated metallic surface.

3. The vacuum chamber for vacuum processing according to claim 2, wherein an emissivity difference between the at least one treated metallic surface and an untreated metallic surface comprising a same metallic material, is in the range of 0.5 to 0.81.

4. The vacuum chamber for vacuum processing according to claim 1, wherein the component is selected from the group of a temperature-controllable component, a measurement device or combinations thereof.

5. The vacuum chamber for vacuum processing according to claim 4, wherein the temperature-controllable component comprises one selected from the group of a substrate, a material provision source, a vacuum chamber wall and a substrate support.

6. The vacuum chamber for vacuum processing according to claim 1, wherein the vacuum chamber comprises the component.

7. The vacuum chamber for vacuum processing according to claim 1, wherein the at least one treated surface has an emissivity in the range of ≥ 0.3 to ≥ 0.7 at 100° C.

8. The vacuum chamber for vacuum processing according to claim 2, wherein the at least one treated metallic surface has an emissivity in the range of ≥ 0.3 to ≥ 0.7 at 100° C.

9. (canceled)

10. The vacuum chamber for vacuum processing according to claim 2, wherein the metallic material is one selected of the group of a transition metal, an alkaline earth metal, a metal of the boron group, a metal alloy or any combinations thereof.

11. The vacuum chamber for vacuum processing according to claim 2, wherein the metallic material comprises one selected of the group of copper, molybdenum, nickel, magnesium, alumina, stainless steel, brass or any combinations thereof.

12. The vacuum chamber for vacuum processing according to claim 1, wherein the at least one treated surface comprises an alumina-magnesium-alloy having an emissivity in the range of ≥ 0.5to ≥ 0.9 at 100° C.

13. The vacuum chamber for vacuum processing according to claim 1, wherein the at least one treated surface comprises copper having an emissivity in the range of ≥ 0.5 to ≥ 0.8 at 100° C.

14. The vacuum chamber for vacuum processing according to claim 1, wherein the treated surface comprises stainless steel having an emissivity in the range of ≥ 0.6 to ≥ 0.9 at 100° C.

15. The vacuum chamber for vacuum processing according to claim 1, wherein the treated surface comprises brass having an emissivity in the range of ≥ 0.6 to ≥ 0.72 at 100° C.

16. The vacuum chamber for vacuum processing according to claim 1, wherein the treated surface comprises molybdenum having an emissivity in the range of ≥ 0.6 to ≥ 0.8 at 100° C.

17. The vacuum chamber for vacuum processing according to claim 1, wherein the at least one device is selected from the group of a chamber wall of the vacuum chamber, a plate, a material provision source, a substrate support, a shield or combinations thereof.

18. The vacuum chamber for vacuum processing according to claim 17, wherein the vacuum chamber comprises one selected of the group of a material provision source and a plate for absorbing thermal radiation from the material provision source, a material provision source comprising a crucible and a heater, the crucible having at least one first treated surface and the heater having at least one second treated surface, the at least one first treated surface and the at least one second treated surface facing each other, and a substrate support, the substrate support having at least one treated surface portion.

19. (canceled)

20. (canceled)

21. The vacuum chamber for vacuum processing according to claim 18, wherein the vacuum chamber further comprises a measurement device, the measurement device being arranged for measuring a value at the at least one treated surface portion.

22. (canceled)

23. A vacuum system comprising
at least one vacuum chamber according to claim 1.

24. (canceled)

25. A method for controlling a temperature in a vacuum system, the method comprising:
treating at least one surface with an ultra-short pulse laser to obtain at least one treated surface, the at least one treated surface being positioned and shaped so as to on selected of the group of providing thermal energy to and absorbing thermal energy from a component;
providing the at least one treated surface in a vacuum chamber;
positioning the component relative to the at least one treated surface; and
providing one selected from thermal energy to and absorbing thermal energy from the component with the at least one treated surface.
